(19) United States
(12) Patent Application Publication
(10) Pub. No.: US 2009/0261441 A1
(43) Pub. Date: Oct. 22, 2009

(54) OPTICAL SEMICONDUCTOR DEVICE

(76) Inventors: Hisatada Yasukawa, Kyoto (JP); Hironari Takehara, Kyoto (JP); Takaki Iwai, Osaka (JP)

Correspondence Address: MCDERMOTT WILL & EMERY LLP, 600 13TH STREET, NW, WASHINGTON, DC, 20005-3096, US

(21) Appl. No.: 12/400,346

(22) Filed: Mar. 9, 2009

(30) Foreign Application Priority Data
Apr. 21, 2008 (JP) 2008-109910

(51) Int. Cl. H01L 31/02; H01L 31/112

(52) U.S. Cl. 257/438; 257/E31.079; 257/E31.11; 257/290

(57) ABSTRACT

An optical semiconductor device includes a light-receiving element on a semiconductor substrate of a first conductivity type, the light-receiving element including a light-receiving portion for converting incident light to an electrical current signal and performing a current amplification. The light-receiving portion includes: a semiconductor layer formed on the semiconductor substrate and having an impurity concentration substantially equal to or less than that of the semiconductor substrate; a first semiconductor region of a second conductivity type formed on the semiconductor layer and having an impurity concentration higher than that of the semiconductor layer; and a second semiconductor region of the first conductivity type selectively formed between the semiconductor substrate and the semiconductor layer and having an impurity concentration higher than those of the semiconductor substrate and the semiconductor layer.

### CROSS REFERENCE TO RELATED APPLICATION

This application claims priority under 35 U.S.C. §119 on Patent Application No. 2008-109910 filed in Japan on Apr. 21, 2008, the entire contents of which are hereby incorporated by reference.

### BACKGROUND OF THE INVENTION

1. Field of the Invention

The present invention relates to an optical semiconductor device and, more particularly, to an optical semiconductor device including a light-receiving element and a logic element formed on the same substrate.

2. Description of the Background Art

An opto-electronic integrated circuit (OEIC) device is a type of an optical semiconductor device, in which a light-receiving element such as a photodiode for converting an optical signal to an electrical signal, active elements such as a transistor element of the peripheral circuit, and passive elements such as a resistor element and a capacitor element are formed on the same substrate. OEIC devices are used as various optical sensor devices and optical pickup devices for optical discs, which are capable of converting an optical signal to an electrical signal.

For an OEIC device used as an optical pickup device, there is a demand for improving the light-receiving sensitivity and increasing the operation speed. Optical pickup devices have recently been used with BDs (Blue Digital Versatile Discs) using blue light, in addition to CDs (Compact Discs) using infrared light and DVDs (Digital Versatile Discs) using red light, and there is a demand for a single optical pickup device to be able to detect three different light source signals of different wavelengths. Thus, there are demands for OEIC devices having a desirable light-receiving sensitivity and a desirable high-speed response property not only for infrared light and red light but also for blue light.

In recent years, for large data transfer between various types of terminals in the field of space transmission technology, the utility value of optical sensor devices for visible light communications using fluorescent lamps or visible light LEDs has been increasing as an alternative technology to replace conventional wireless communications devices. Particularly, with the fast-paced development of LED lighting devices aiming at reducing the power consumption by lighting devices, the visible light communications technology using indoor lighting has come to a point where high-speed data transfer can be realized using such LEDs for lighting devices. Thus, as means for household space transmission network communications, for example, the visible light communications technology is expected to be the mainstream of the space transmission technology in the future.

As a first conventional example, the structure of an amplification-type photodiode element will now be described (see, for example, Patent Document 1).

FIG. 6A is a cross-sectional view showing an optical semiconductor device of the first conventional example. As shown in FIG. 6A, the optical semiconductor device of the first conventional example includes a semiconductor substrate 81 of a P-type silicon (Si) having a low impurity concentration and having a specific resistance of 150 Ω·cm, an N⁺-type semiconductor layer 82 of a semiconductor having a high impurity concentration formed thereon, and a P⁻-type semiconductor layer 83 having an impurity concentration lower than that of the N⁺-type semiconductor layer 82 formed on the N⁺-type semiconductor layer 82. A P⁺-type semiconductor layer 84 having an impurity concentration higher than that of the P⁺-type semiconductor layer 83 is formed on the P⁻-type semiconductor layer 83.

A P⁺⁺-type semiconductor layer 85 having an impurity concentration higher than that of the P⁺-type semiconductor layer 84 is formed on a peripheral portion of the P⁺-type semiconductor layer 84. The P⁺⁺-type semiconductor layer 85 serves as an anode contact of a photodiode.

An N⁺⁺-type semiconductor layer 86 is formed at an edge portion of the N⁺-type semiconductor layer 82 so as to run through the P⁻-type semiconductor layer 83. The N⁺⁺-type semiconductor layer 86 serves as a cathode contact layer of a photodiode. A device isolation layer 91 is formed between the N⁺⁺-type semiconductor layer 86 and the P⁺-type semiconductor layer 84 and the P⁺⁺-type semiconductor layer 85. A passivation film 92 is formed so as to cover the N⁺⁺-type semiconductor layer 86, the P⁺-type semiconductor layer 84 and the P⁺⁺-type semiconductor layer 85. An anode electrode 87 is formed running through the protection film 92 to be connected to the P⁺⁺-type semiconductor layer 85, which is to be an anode contact layer, and a cathode electrode 88 is formed running through the protection film 92 to be connected to the N⁺⁺-type semiconductor layer 86, which is to be a cathode contact layer. Reference numeral 89 denotes a light-receiving region of a light-receiving element (i.e., a light-receiving portion for converting incident light to an electrical current signal and for performing a current amplification) in the optical semiconductor device of the first conventional example.

The operation of the light-receiving portion in the optical semiconductor device of the first conventional example having such a configuration will now be described with reference to FIGS. 6A-6C. FIG. 6B shows the vertical impurity concentration profile (the impurity concentration profile between points a and b) in the optical semiconductor device of the first conventional example shown in FIG. 6A, and FIG. 6C shows the vertical energy band profile (the energy band profile between points a and b) in the optical semiconductor device of the first conventional example.

First, in the optical semiconductor device of the first conventional example, light incident on a light-receiving region 89 passes through the passivation film layer 92 and impinges on the surface of the P⁺-type semiconductor layer 84. Since photons of the incident light are exponentially absorbed into the semiconductor according to the optical absorption coefficient, which is a physical constant, the incident light is attenuated while traveling into lower semiconductor layers, and eventually becomes extinct. Photons absorbed into the semiconductor form electron-hole pairs and generate a photoelectric current. As shown in FIG. 6B, the P⁺-type semiconductor layer 84 near the device surface is a high-concentration region. As shown in FIG. 6C, the energy band of this high-concentration region is flat, whereby the transport of the electron-hole pairs generated by photons absorbed in this high-concentration region is dominated by diffusion.

Then, in the optical semiconductor device of the first conventional example, incident light, which has passed through the P⁺-type semiconductor layer 84, is incident on the surface of the P⁻-type semiconductor layer 83. As shown in FIG. 6B, the P⁻-type semiconductor layer 83 is a low-concentration region with a concentration gradient, whereby the electron-hole pairs generated in the P⁻-type semiconductor layer 83 act in the electrical potential gradient region (depletion layer region) shown in FIG. 6C. Therefore, the transport of the electron-hole pairs generated in the P⁻-type semiconductor layer 83 is dominated by electric field drift, whereby the response speed will be highest in the P⁻-type semiconductor layer 83. By applying a high voltage between the anode electrode 87 and the cathode electrode 88, the potential energy difference in the electrical potential gradient region of the P⁻-type semiconductor layer 83 substantially increases, thereby increasing the electrical potential gradient. Thus, by the application of a high voltage, it is possible to cause the amplification of the generated carriers (avalanche amplification), thereby amplifying the photoelectric current.

As a second conventional example, the structure of an amplification-type photodiode element will now be described (see, for example, Patent Document 2).

FIG. 7A is a cross-sectional view showing an optical semiconductor device of the second conventional example. In FIG. 7A, like elements to those of the optical semiconductor device of the first conventional example shown in FIG. 6A are denoted by like reference numerals and will not be further described below. As shown in FIG. 7A, the optical semiconductor device of the second conventional example differs from the optical semiconductor device of the first conventional example shown in FIG. 6A in that a P⁺-type semiconductor layer 90 having a concentration higher than that of the P⁻-type semiconductor layer 83 and lower than that of the N⁺-type semiconductor layer 82 is selectively formed inside the P⁻-type semiconductor layer 83. With the provision of the P⁺-type semiconductor layer 90, the P⁺-type semiconductor layer 84 of the optical semiconductor device of the second conventional example is formed to be thinner than that of the optical semiconductor device of the first conventional example.

The operation of the light-receiving portion in the optical semiconductor device of the second conventional example having such a configuration will now be described with reference to FIGS. 7A-7C. FIG. 7B shows the vertical impurity concentration profile (the impurity concentration profile between points a and b) in the optical semiconductor device of the second conventional example shown in FIG. 7A, and FIG. 7C shows the vertical energy band profile (the energy band profile between points a and b) in the optical semiconductor device of the second conventional example.

A characteristic of the optical semiconductor device of the second conventional example is that a high-concentration region is formed in the P⁻-type semiconductor layer 83 by the P⁺-type semiconductor layer 90 as shown in FIGS. 7A and 7B. Therefore, as shown in the energy band structure of FIG. 7C, even when a low voltage is applied between the anode electrode 87 and the cathode electrode 88, a large electrical potential gradient can be realized by the P⁺-type semiconductor layer 90 between the P⁺-type semiconductor layer 90 and the N⁺-type semiconductor layer 82. Thus, in the region where the large electrical potential gradient is present, it is possible with the application of a low voltage to cause an amplification (avalanche amplification) of the generated carriers, and to thereby amplify the photoelectric current.

An OEIC device in which a photodiode element and a bipolar transistor element are formed monolithically will now be described as a third conventional example (see, for example, Patent Document 3).

FIG. 8 is a cross-sectional view of an optical semiconductor device of the third conventional example. As shown in FIG. 8, in the optical semiconductor device of the third conventional example, a P⁺-type semiconductor layer 102 of a semiconductor having a high impurity concentration is formed on a semiconductor substrate 101 of a P-type silicon (Si) having a low impurity concentration and a specific resistance of 150 Ω·cm, and a P⁻-type semiconductor layer 103 having an impurity concentration lower than that of the P⁺-type semiconductor layer 102 is formed on the P⁺-type semiconductor layer 102. An N-type semiconductor layer 104 having an impurity concentration higher than that of the P⁻-type semiconductor layer 103 is formed on the P⁻-type semiconductor layer 103. The impurity concentration peak position in the P⁺-type semiconductor layer 102 is set to be at a depth of about 10 μm from the upper surface of the N-type semiconductor layer 104. The thickness of the N-type semiconductor layer 104 is set to be 2 μm for the formation of a VPNP-Tr (vertical-type PNP bipolar transistor).

A light-receiving element portion 100, a first transistor portion 200 and a second transistor portion 220 are formed in the P⁻-type semiconductor layer 103 and the N-type semiconductor layer 104. The light-receiving element portion 100, the first transistor portion 200 and the second transistor portion 220 are electrically insulated from one another by a device isolation film 105. A passivation film 150 is formed on the N-type semiconductor layer 104, except for the electrode formation regions, so as to cover the light-receiving element portion 100, the first transistor portion 200 and the second transistor portion 220.

An N⁺-type semiconductor region 106 having an impurity concentration higher than that of the N-type semiconductor layer 104 is formed in an uppermost portion of the N-type semiconductor layer 104 in the light-receiving element portion 100. The thickness of an N⁺-type semiconductor region 106 is 0.15 μm or less. The cathode of the light-receiving element portion 100 includes a cathode contact region 107 formed in a peripheral portion of the N⁺-type semiconductor region 106, an N-type polycrystalline semiconductor layer 108a formed on the cathode contact region 107, and a cathode electrode 109 formed on the N-type polycrystalline semiconductor layer 108a. The anode of the light-receiving element portion 100 includes a P⁺-type buried region 110 formed in a peripheral portion of the light-receiving element portion 100, a P-type anode contact region 111 formed on the P⁺-type buried region 110, a P-type polycrystalline semiconductor layer 112 formed on an anode contact region 111, and an anode electrode 113 formed on the P-type polycrystalline semiconductor layer 112. The cathode contact region 107 and the P-type anode contact region 111 are electrically insulated from each other by the device isolation film 105.

The first transistor portion 200, in which an NPN bipolar transistor is provided, is formed on the N-type semiconductor layer 104, and is electrically insulated from the light-receiving element portion 100 and the second transistor portion 220 by the device isolation film 105 and the P⁺-type buried region 110. The collector of the first transistor portion 200 includes a buried collector region 114, an N-type collector contact region 115 formed on the buried collector region 114, an N-type polycrystalline semiconductor layer 108b formed on the N-type collector contact region 115, and a collector electrode 116 formed on the N-type polycrystalline semiconductor layer 108b. The base portion of the first transistor portion 200 includes an active base region 117 formed on the buried collector region 114, a contact base region 118 formed to be adjacent to the active base region 117, the P-type polycrystalline semiconductor layer 112 formed on the contact base region 118, and a base electrode 120 formed on the P-type polycrystalline semiconductor layer 112. The emitter portion of the first transistor portion 200 includes an emitter region 119 formed on the active base region 117, an N-type polycrystalline semiconductor layer 108c formed on the emitter region 119, and an emitter electrode 121 formed on the N-type polycrystalline semiconductor layer 108c.

In the second transistor portion 220, in which a VPNP-Tr is provided, an N-type buried layer 130 is formed in the P⁻-type semiconductor layer 103, and a P-type buried collector region 131 is formed in the N-type semiconductor layer 104 on the P⁻-type semiconductor layer 103. Thus, the P-type buried collector region 131 is formed on the N-type buried layer 130. The thickness of the N-type semiconductor layer 104 is set to be about 2 μm for sufficiently ensuring the P-type buried collector region 131. The collector of the second transistor portion 220 includes the P-type buried collector region 131, a collector contact region 132 formed on the P-type buried collector region 131, an N-type polycrystalline semiconductor layer 108d formed on the collector contact region 132, and a collector electrode 133 formed on the N-type polycrystalline semiconductor layer 108d. The base of the second transistor portion 220 includes an active base region 134 formed on the P-type buried collector region 131, a contact base region 135 formed to be adjacent to the active base region 134, the P-type polycrystalline semiconductor layer 112 formed on the contact base region 135, and a base electrode 136 formed on the P-type polycrystalline semiconductor layer 112. The emitter of the second transistor portion 220 includes an emitter region 137 formed on the active base region 134, an N-type polycrystalline semiconductor layer 108e formed on the emitter region 137, and an emitter electrode 138 formed on the N-type polycrystalline semiconductor layer 108e. As described above, with the configuration as shown in FIG. 8, it is possible to form a VPNP-Tr as the second transistor portion 220.

The operation of the light-receiving element portion in the optical semiconductor device of the third conventional example having such a configuration will be described with reference to FIGS. 8, 9A and 9B. FIG. 9A shows the vertical impurity configuration profile in the light-receiving element portion of the optical semiconductor device of the third conventional example shown in FIG. 8, and FIG. 9B shows the vertical energy band profile in the light-receiving element portion of the optical semiconductor device of the third conventional example.

In the optical semiconductor device of the third conventional example, light incident on the light-receiving element portion 100 first impinges on the surface of the N⁺-type semiconductor region 106, passes through the N⁺-type semiconductor region 106, and then impinges on the surface of the N-type semiconductor layer 104. As shown in FIGS. 9A and 9B, the carriers generated in the N⁺-type semiconductor region 106 and the N-type semiconductor layer 104 are accelerated by the electrical potential gradient a caused by the impurity concentration difference between the N-type semiconductor layer 104 and the N⁺-type semiconductor region 106, and then travel by diffusion through the flat region d of the N-type semiconductor layer 104. The traveling carriers reach the P⁻-type semiconductor layer 103. Since a reverse bias voltage is applied in advance to the cathode electrode 109 of the light-receiving element portion 100, a depletion layer is formed in a region from the P⁻-type semiconductor layer 103 to the P⁺-type semiconductor layer 102 that is surrounded by the P⁺-type buried region 110 located at the peripheral portion of the light-receiving element portion 100. Therefore, the carriers, which have reached the P⁻-type semiconductor layer 103, rapidly travel through the depletion layer as a drift current, whereby the light-receiving element portion 100 can be provided with a high-speed response.

While incident light that has reached the semiconductor substrate 101 generates carriers in the semiconductor substrate 101, the generated carriers travel in arbitrary directions by diffusion. The traveling speed of the carriers, which is dictated by the diffusion, is slow, and some of the carriers become extinct through recombination. Although carriers that do not become extinct through recombination reach the vicinity of the P⁺-type semiconductor layer 102, the electrons which are the carriers cannot reach the P⁺-type semiconductor layer 102 and the P⁻-type semiconductor layer 103 from the semiconductor substrate 101 but become extinct through recombination because of the presence of a potential barrier due to the impurity concentration difference between the P⁺-type semiconductor layer 102 and the semiconductor substrate 101. Therefore, carriers traveling by diffusion through the semiconductor substrate 101 can be made substantially all extinct, whereby the light-receiving element portion 100 can be provided with a higher-speed response.

Patent Document 1: Japanese Laid-Open Patent Publication No. 2000-252507

Patent Document 2: Japanese Laid-Open Patent Publication No. H11-45988

Patent Document 3: Japanese Laid-Open Patent Publication No. 2006-120984

### SUMMARY OF THE INVENTION

There are three types of optical pickup devices, i.e., those for CDs using infrared light, those for DVDs using red light, and those for high-density DVDs using blue light. With optical pickup devices for high-density DVDs, there is a demand for a high-speed response property because of the high data density of high-density DVDs. Therefore, with a light-receiving device for signal detection in an optical pickup device, there is a demand for a sufficient light-receiving sensitivity and a sufficient high-speed response property for blue light. The amount of light absorbed by a semiconductor for each of the wavelengths of the three types of light (infrared light, red light and blue light) will now be described. The amount of light absorbed by a semiconductor depends on the wavelength of the incident light, and the amount of light having a particular wavelength to be absorbed by a semiconductor at a depth of t from the plane of incidence can be expressed as 1-e^{αt} (where e is the base of natural logarithms, and α is the absorption coefficient of the semiconductor for the incident light of the particular wavelength). For example, the depth from the plane of incidence at which about 90% of the incident light has been absorbed by a silicon semiconductor is about 24 μm for infrared light having a wavelength of 780 nm, about 7.7 μm for red light having a wavelength of 650 nm, and about 0.6 μm for blue light having a wavelength of 405 nm.

In order to improve the light-receiving characteristics, i.e., the light-receiving sensitivity and the response speed, of a light-receiving device, there is needed a structure capable of efficiently generating electron-hole pairs with respect to the number of photons, which is dependent on the wavelength of light, and efficiently electrically extracting the electrons or holes as carriers, which contribute to the current.

A light-receiving element for use in a visible light communications device is required to ensure a sufficient space transmission distance and to be capable of detecting a high-frequency optical signal. The characteristic of the illumination light to be the signal source is that it is light illuminating a wide area and it is white light. The light-receiving characteristic for light illuminating a wide area is that since the amount of light per unit area is dependent on the distance with wide-area illumination, the amount of incident light to be taken into the light-receiving region varies depending on the transmission distance. Moreover, white light contains the complete spectrum of wavelengths in the visible light range. Therefore, a light-receiving element for use in a visible light communications device is required to have a sufficient light-receiving sensitivity across the entire spectrum of the visible light wavelengths. Moreover, a light-receiving element for signal detection is required to sufficiently detect an optical signal within the space transmission distance, and is therefore required to have a high light-receiving sensitivity. Specifically, there is needed such a light-receiving sensitivity that an optical signal can be detected within a distance of a few meters in a case where a household lighting is used, and a few tens of meters in a case where a commercial lighting is used.

Moreover, with devices using light-receiving elements as described above, there is a demand for reducing the power consumption in view of the environmental conservation, against a possible increase in the power consumption caused by the increase in the functions of the signal control circuit for the purpose of realizing a higher functionality.

As described above, a light-receiving element is required to have a high light-receiving sensitivity and a high-speed response property in a low-voltage operation, irrespective of the specific application.

As shown in FIG. 6A, in the optical semiconductor device of the first conventional example, the P⁻-type semiconductor layer 83 is formed with a large thickness so as to ensure a sufficient absorption of long-wavelength light and to realize a low capacitance, in order to realize a high light-receiving sensitivity and a high-speed response property for the entire wavelength range. Moreover, in the optical semiconductor device of the first conventional example, it is necessary to form a depletion layer of a sufficient size between the N⁺-type semiconductor layer 82 and the P⁺-type semiconductor layer 84 as shown in FIGS. 6B and 6C. For example, with red light having a wavelength of 650 nm, the thickness of the depletion layer is a region having a thickness of 7.7 μm or more.

However, in order to cause an avalanche amplification in such a depletion layer, it is necessary to achieve a reverse bias state of about 60 V or more, thus requiring a large amount of power, and it is not possible to realize a reduction in the power consumption.

In view of this, there is proposed an optical semiconductor device of the second conventional example as shown in FIG. 7A in order to realize both a low-voltage operation and an amplification operation. In the optical semiconductor device of the second conventional example, the P⁻-type semiconductor layer 83 is formed as a thin region between the P⁺-type semiconductor layer 90 and the P⁺-type semiconductor layer 84 as shown in FIG. 7B. Therefore, as shown in FIG. 7C, a depletion layer having a large electrical potential gradient is formed in the region of the P-type semiconductor layer 83 interposed between the P⁺-type semiconductor layer 90 and the P⁺-type semiconductor layer 84, whereby it is possible to realize an avalanche amplification with the application of a low voltage.

However, in the optical semiconductor device of the second conventional example, electrons and holes generated by light absorption in the region from the device surface to the vicinity of the P⁺-type semiconductor layer 90 cannot contribute to the avalanche amplification. Therefore, it is not possible to realize a high light-receiving sensitivity for short-wavelength light.

In the optical semiconductor device of the third conventional example shown in FIG. 8, the thickness of the N-type semiconductor layer 104 is set to be as small as 2 μm, thereby resulting in a structure where the flat region d where the electrical potential gradient is flat is dominant as shown in FIG. 9B. This increases the traveling distance of carriers that travel through the flat region d, thereby increasing the amount of time before the carriers reach the depletion layer generated by the P⁻-type semiconductor layer 103 and the N-type semiconductor layer 104. As a result, the response speed is deteriorated. Moreover, an increase in the traveling distance of the carriers also increases the amount of carrier recombination, thereby deteriorating the light-receiving sensitivity.

Particularly, for blue light having a wavelength of 405 nm, the depth from the plane of incidence at which about 90% of the incident light has been absorbed by a silicon semiconductor is about 0.6 μm, and therefore carriers are generated in the non-depletion layer region at the device surface, whereby the influence of the increase in the traveling distance of carriers is more pronounced, thus significantly deteriorating the response speed and the light-receiving sensitivity. In the optical semiconductor device of the third conventional example, if the N-type semiconductor layer 104 is made thicker, the sensitivity of the light-receiving element will be improved, but the characteristics of a transistor formed on the same substrate will be deteriorated. Thus, where a light-receiving element and a transistor (particularly, a VPNP-Tr) are formed on the same substrate, there is a trade-off between the light-receiving sensitivity and the transistor characteristics, which are both dependent on the thickness of the N-type semiconductor layer 104, and it is difficult to improve the light-receiving sensitivity and the transistor characteristics both at the same time.

In the optical semiconductor device of the third conventional example, a high-resistance region of the P⁻-type semiconductor layer 103 is present between the P⁺-type buried region 110 and the P⁺-type semiconductor layer 102 as shown in FIG. 8, thereby deteriorating the frequency characteristics of the light-receiving element portion 100. The optical semiconductor device of the third conventional example has a layout such that the width of the P⁺-type buried region 110 is relatively large in order to reduce the series resistance, which however enlarges the peripheral region of the light-receiving element portion 100, thus preventing a reduction in the chip area.

Moreover, with any of the conventional examples, blue light has a wavelength shorter than those of red light and infrared light, and therefore has a larger amount of energy per photon, hence a smaller number of photons for the same optical output power. Therefore, the amount of carriers generated by blue light is smaller, thus decreasing the light-receiving sensitivity. Specifically, with the quantum yield being 100% (at which one electron-hole pair is generated for each photon), the light-receiving sensitivity is 0.63 A/W for infrared light having a wavelength of 780 nm, 0.52 A/W for red light having a wavelength of 650 nm, and 0.33 A/W for blue light having a wavelength of 405 nm. Therefore, an OEIC compatible with blue light needs to have a gain resistance higher than those of other circuits for other wavelengths, thereby resulting in a deterioration of the circuit frequency characteristics. Moreover, with the low light-receiving sensitivity for blue light, the OEIC will have poor noise characteristics.

In view of the above, the present invention has an object to improve the operation characteristics (the light-receiving sensitivity and the high-speed response property) of a light-receiving element of an optical semiconductor device, and to provide an optical semiconductor device on which a light-receiving element can easily be mounted together with an element such as an NPN transistor or a VPNP transistor.

In order to achieve the object above, the present invention provides an optical semiconductor device, including a light-receiving element on a semiconductor substrate of a first conductivity type, the light-receiving element including a light-receiving portion for converting incident light to an electrical current signal and performing a current amplification, the light-receiving portion including: a semiconductor layer formed on the semiconductor substrate and having an impurity concentration substantially equal to or less than that of the semiconductor substrate; a first semiconductor region of a second conductivity type formed on the semiconductor layer and having an impurity concentration higher than that of the semiconductor layer; and a second semiconductor region of the first conductivity type selectively formed between the semiconductor substrate and the semiconductor layer and having an impurity concentration higher than those of the semiconductor substrate and the semiconductor layer.

With the optical semiconductor device of the present invention, the light-receiving element including the light-receiving portion for generating a photoelectric current and performing the current amplification is provided on the semiconductor substrate. Therefore, it is possible to convert the optical signal received as incident light to a photoelectric current and to amplify the photoelectric current, whereby it is possible to detect an optical signal even if the power of the incident light is small.

Particularly, in the optical semiconductor device of the present invention, an avalanche amplification can be performed with the application of a low voltage in the semiconductor layer interposed between the first semiconductor region of the second conductivity type having a high impurity concentration and the second semiconductor region of the first conductivity type having a high impurity concentration, whereby it is possible to amplify a photoelectric current carrying optical signal information. Therefore, it is possible to improve the light-receiving sensitivity without increasing the thickness of the first semiconductor region of the second conductivity type, and it is thus possible to also improve the high-speed response property. Moreover, since it is not necessary to increase the thickness of the first semiconductor region of the second conductivity type, it is possible to improve the light-receiving sensitivity not only for infrared light and red light, but also for blue light. Moreover, since the second semiconductor region of the first conductivity type is selectively formed between the semiconductor substrate and the semiconductor layer, the semiconductor layer having a low impurity concentration is present even at a position sufficiently distant from the first semiconductor region of the second conductivity type in a region where the second semiconductor region is absent, whereby the electrical potential gradient will be relatively small and the depletion layer will be sufficiently expanded. Therefore, it is possible to realize a reduction in the capacitance, and it is thus possible to also improve the frequency characteristics.

Moreover, with the optical semiconductor device of the present invention, the process of forming each semiconductor region of the light-receiving element and the process of forming each semiconductor region of the transistor may share a common process, and therefore the light-receiving element and the various transistors can easily be integrated together on the same substrate.

Moreover, with the optical semiconductor device of the present invention, the light-receiving sensitivity of the light-receiving element can be made sufficiently high without employing a special configuration, e.g., increasing the thickness of the first semiconductor region of the second conductivity type. Therefore, when various transistors are provided on the same substrate, it is possible to reduce the restrictions to be imposed on the structure of each transistor in order to ensure the characteristics of the light-receiving element.

As described above, according to the present invention, the current formed by the carriers generated in the first semiconductor region or the semiconductor layer can be amplified by the light-receiving portion, whereby it is possible to obtain a sufficient light-receiving sensitivity and a sufficient high-speed response property even for light of a short wavelength such as blue light. With the second semiconductor region, the avalanche voltage for causing the current amplification can be set to a low voltage, whereby it is possible to reduce the power consumption of the optical semiconductor device, allowing for its use in a wide range of applications.

Thus, the optical semiconductor device of the present invention is capable of reliably detecting optical signals of different wavelengths even with a low output power, and is therefore suitable for, for example, an optical detection device using a plurality of types of light for use with DVDs, etc.

### BRIEF DESCRIPTION OF THE DRAWINGS

FIG. 1 is a cross-sectional view showing an example of a light-receiving element portion in an optical semiconductor device according to a first example embodiment.

FIGS. 2A-2C illustrate the principle of the current amplification by the light-receiving element portion in the optical semiconductor device according to the first example embodiment.

FIGS. 3A and 3B illustrate the principle of the current amplification by the light-receiving element portion in the optical semiconductor device according to the first example embodiment.

FIGS. 4A and 4B illustrate the principle of the current amplification by the light-receiving element portion in the optical semiconductor device according to the first example embodiment.

FIG. 5 is a cross-sectional view showing an example of an optical semiconductor device according to a second example embodiment.

FIG. 6A is a cross-sectional view showing an optical semiconductor device of a first conventional example, FIG. 6B shows the impurity concentration profile between points a and b in FIG. 6A, and FIG. 6C shows the energy band profile between points a and b in FIG. 6A.

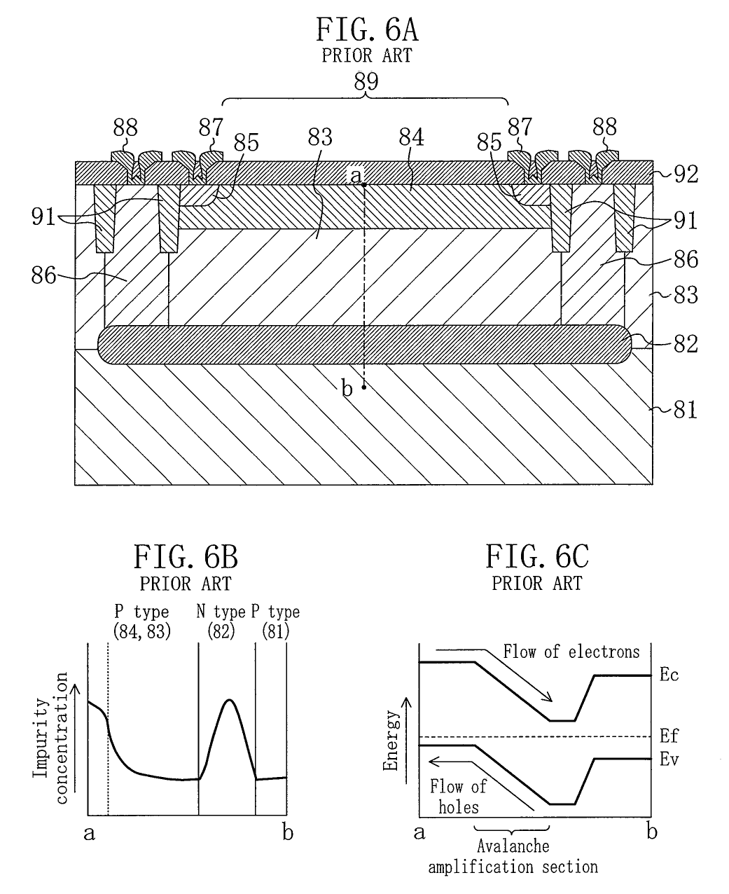

FIG. 7A is a cross-sectional view showing an optical semiconductor device of a second conventional example, FIG. 7B shows the impurity concentration profile between points a and b in FIG. 7A, and FIG. 7C shows the energy band profile between points a and b in FIG. 7A.

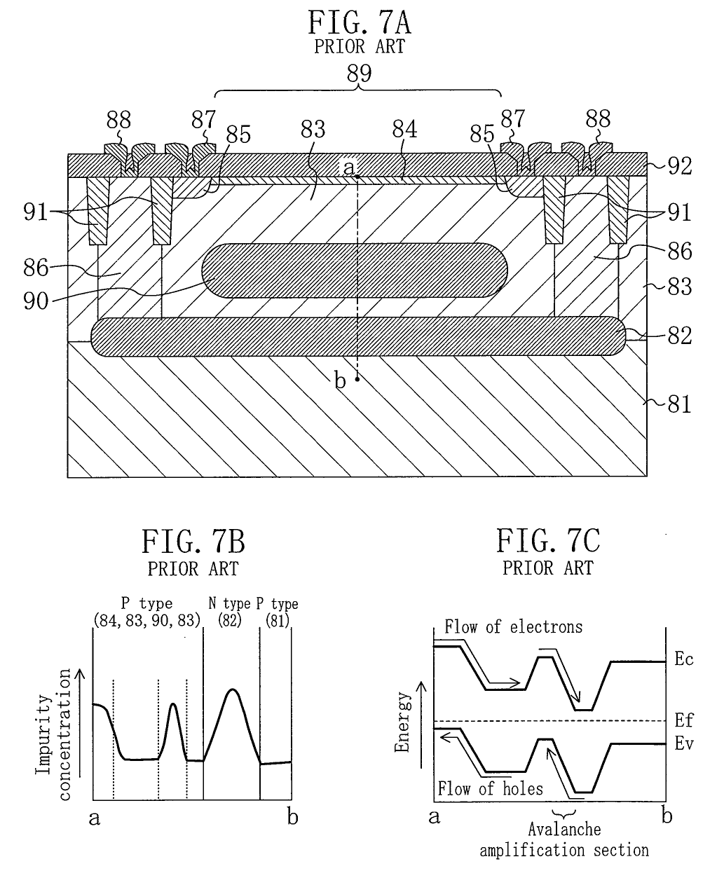

FIG. 8 is a cross-sectional view of an optical semiconductor device of a third conventional example.

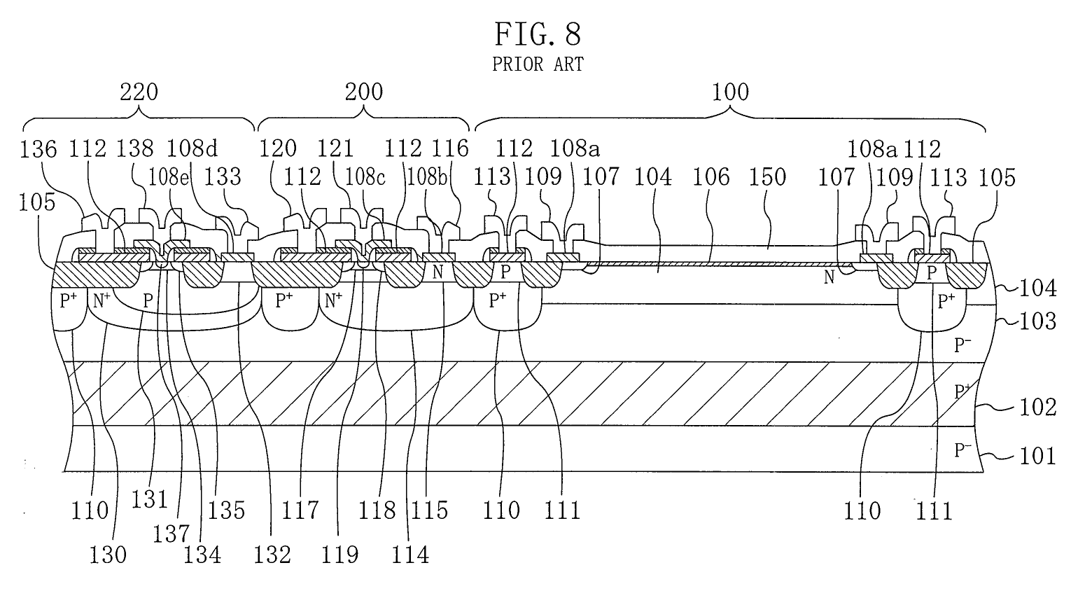

FIG. 9A shows the vertical impurity concentration profile in a light-receiving element portion of the optical semiconductor device of the third conventional example, and FIG. 9B shows the vertical energy band profile in the light-receiving element portion of the optical semiconductor device of the third conventional example.

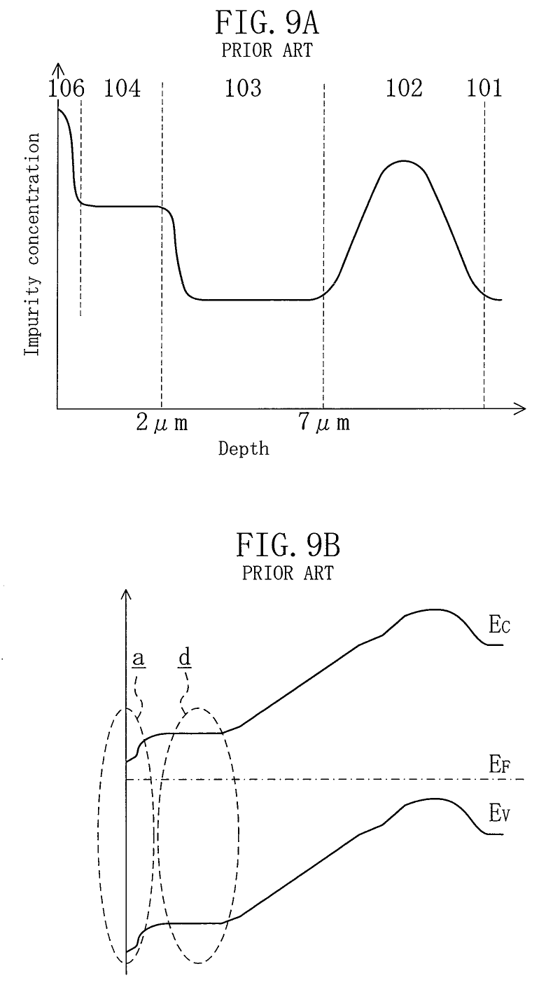

### DETAILED DESCRIPTION OF THE INVENTION

### First Example Embodiment

An optical semiconductor device according to a first example embodiment will now be described with reference to the drawings. Specifically, the first example embodiment is directed to an optical semiconductor device provided with a light-receiving element having a light-receiving portion for converting incident light to an electrical current signal and performing a current amplification.

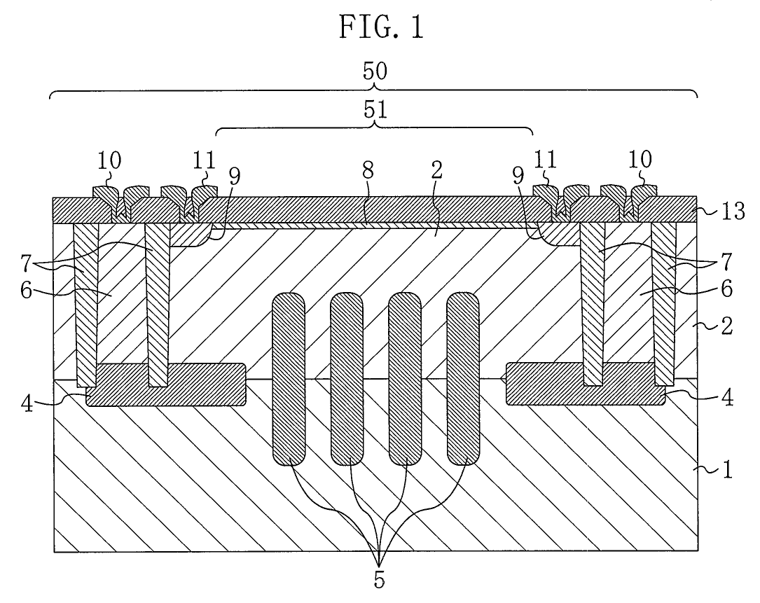

FIG. 1 is a cross-sectional view showing an example of a light-receiving element portion in the optical semiconductor device of the first example embodiment. A light-receiving element portion 50 of the present embodiment performs a current amplification by an avalanche amplification near the surface within a light-receiving region (light-receiving operation part) 51 for converting incident light to an electrical current signal.

As shown in FIG. 1, the device includes a P⁻-type semiconductor substrate 1 of a P-type silicon (Si) having a low impurity concentration (e.g., about 1×10⁴ cm⁻³) and a specific resistance of about 100 Ω·cm to 200 Ω·cm, for example, and a P⁻-type semiconductor layer 2 having a thickness of 2 μm and an impurity concentration (e.g., about 1×10¹⁴ cm⁻³) substantially equal to or less than that of the P⁻-type semiconductor substrate 1, for example, which is epitaxially grown on the P⁻-type semiconductor substrate 1.

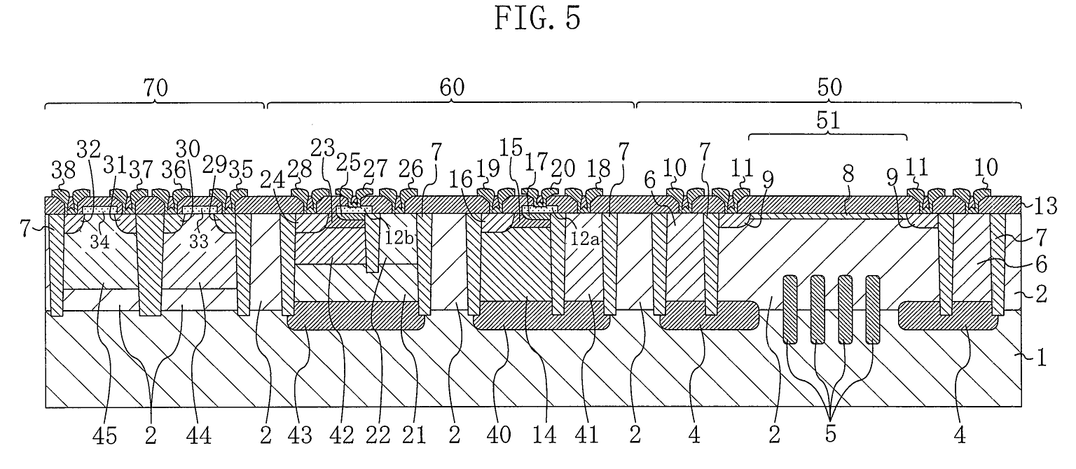

The principal plane (circuit formation plane) of the epitaxial substrate obtained as described above is divided into regions for the light-receiving element portion 50, a first transistor portion 60 and a second transistor portion 70 (see FIG. 5 for the transistor portions 60 and 70) by a device isolation layer 7 obtained by filling locally-formed trenches with silicon oxide (SiO₂). Below a region between an anode electrode 10 and a cathode electrode 11, and at the boundary between the light-receiving element portion 50 and the first transistor portion 60, the device isolation layer 7 is formed to be deeper than the P⁻-type semiconductor layer 2. A protection insulative film 13 of silicon oxide, for example, is formed as a passivation film on the principal plane of the epitaxial substrate, except for the positions of the anode electrode 10, the cathode electrode 11 and electrodes of other transistor portions (see the second example embodiment).

As shown in FIG. 1, in the present embodiment, a high-concentration N⁺-type semiconductor region 8 having a thickness of 0.2 μm and an impurity concentration of about 1×10¹⁸ cm⁻³ is formed in a surface portion of the P⁻-type semiconductor layer 2. The impurity concentration peak position of the N⁺-type semiconductor region 8 is at the depth of, for example, about 0.1 μm from the upper surface of the P⁻-type semiconductor layer 2. The N⁺-type semiconductor region 8 may be provided on the P⁻-type semiconductor layer 2. A cathode contact layer 9 is formed at an edge portion of the N⁺-type semiconductor region 8 by, for example, selectively implanting ions of an N-type impurity at a high concentration and then annealing the N-type impurity. The cathode electrode 11 is formed on the cathode contact layer 9, running through the protection insulative film 13.

A characteristic of the present embodiment is that a P⁺-type semiconductor region 5 having a higher impurity concentration (e.g., 1×10¹⁸ cm⁻³) than that of the P⁻-type semiconductor substrate 1 and than that of the P⁻-type semiconductor layer 2 is selectively formed between the P⁻-type semiconductor substrate 1 and the P⁻-type semiconductor layer 2. Specifically, the P⁺-type semiconductor region 5 is not provided across the entire surface of the light-receiving operation part 51, as is in the prior art, but is provided as a plurality of portions separate from one another. In other words, there are regions where the P⁺-type semiconductor region 5 is absent between the P⁻-type semiconductor substrate 1 and the P⁻-type semiconductor layer 2 in the light-receiving operation part 51. Each portion of the P⁺-type semiconductor region 5 is arranged in a region surrounded by the device isolation layer 7 delimiting the light-receiving operation part 51. The P⁺-type semiconductor region 5 is formed by, for example, selectively implanting a P-type impurity at a high concentration into an upper portion of the P⁻-type semiconductor substrate 1 followed by annealing for activation of the P-type impurity, before the formation of the P⁻-type semiconductor layer 2, and then epitaxially growing the P⁻-type semiconductor layer 2. The P⁺-type semiconductor region 5 has a range of diffusion of about 1 μm above the interface between the P⁻-type semiconductor substrate 1 and the P⁻-type semiconductor layer 2.

As shown in FIG. 1, on the outer side of the cathode contact layer 9 (opposite to the light-receiving operation part 51), a P⁺-type semiconductor region 6 having a thickness of 2 μm and a higher impurity concentration (e.g., 1×10¹⁸ cm⁻³) than that of the P⁻-type semiconductor substrate 1, for example, is selectively formed by ion implantation, with the device isolation layer 7 interposed therebetween. The cathode contact layer 9 and the P⁺-type semiconductor region 6 are electrically insulated from each other by the device isolation layer 7. That is, the light-receiving operation part 51 is delimited by the device isolation layer 7. The impurity concentration peak position of the P⁺-type semiconductor region 6 is at the depth of, for example, about 1 μm from the upper surface of the P⁻-type semiconductor layer 2. Under the P⁺-type semiconductor region 6 (between the P⁺-type semiconductor region 6 and the P⁻-type semiconductor substrate 1), a P⁺-type semiconductor region 4 having a higher impurity concentration (e.g., 1×10¹⁸ cm⁻³) than that of the P⁻-type semiconductor substrate 1 is selectively formed by ion implantation. The P⁺-type semiconductor region 4 has a range of diffusion of about 0.3 μm above the interface between the P⁻-type semiconductor substrate 1 and the P⁻-type semiconductor layer 2. Below the region between the anode electrode 10 and the cathode electrode 11, the device isolation layer 7 is formed so as to extend into the P⁺-type semiconductor region 4. In other words, the bottom of the device isolation layer 7 is located above the bottom of the P⁺-type semiconductor region 4. Moreover, the anode electrode 10 is formed on the P⁺-type semiconductor region 6, running through the protection insulative film 13.

The impurity concentration of the P⁺-type semiconductor region 5, which is a characteristic of the present embodiment, is preferably substantially equal to or greater than that of the P⁺-type semiconductor region 4. Then, a depletion layer is formed in the P⁻-type semiconductor layer 2 interposed between the N⁺-type semiconductor region 8 and the P⁺-type semiconductor region 5, whereby the operation of taking in the photoelectric current at an upper portion of the P⁺-type semiconductor region 5 becomes dominant. Conversely, if the impurity concentration of the P⁺-type semiconductor region 4 is higher than that of the P⁺-type semiconductor region 5, a depletion layer is formed on the upper side of the P⁺-type semiconductor region 4, whereby it is not possible to sufficiently realize the effects of the P⁺-type semiconductor region 5, which will be described later.

In the present embodiment, the cathode electrode 11 and the anode electrode 10 are each provided in a ring-shaped pattern as viewed from above. The P⁺-type semiconductor region 6 is provided so as to surround the N⁺-type semiconductor region 8, the P⁻-type semiconductor layer 2 and the cathode contact layer 9, with the device isolation layer 7 interposed therebetween. By this arrangement, it is possible to mitigate the electric field localization during operation.

A major difference between the conventional optical semiconductor device, and the light-receiving element portion 50 of the present embodiment including impurity diffusion regions and isolation regions described above lies in that the P⁺-type semiconductor region 5 including a plurality of strip-shaped portions arranged side by side is provided at a relatively deep position in the epitaxial substrate.

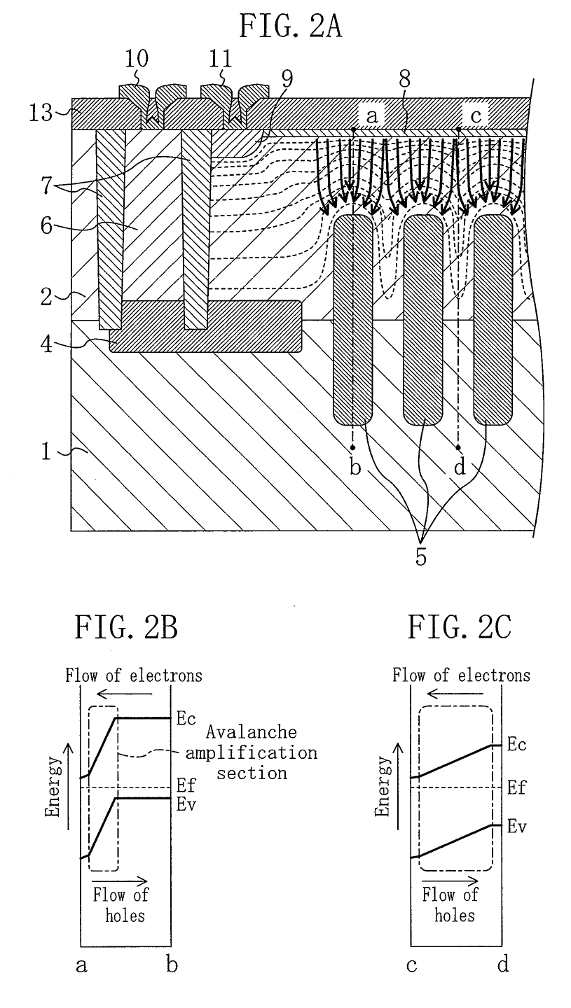

The principle of the current amplification by the light-receiving operation part 51 of the present embodiment will now be described. FIG. 2A is similar to the cross-sectional view of FIG. 1 with the addition of equipotential lines (broken lines in the figure) and lines of electric force (arrows in the figure) for illustrating the light-receiving operation and the current amplification operation by the light-receiving operation part 51 of the present embodiment, FIG. 2B shows the energy band profile between points a and b in FIG. 2A, and FIG. 2C shows the energy band profile between points c and d in FIG. 2A.

First, in the light-receiving operation part 51 of the present embodiment, electron-hole pairs are generated in the P⁻-type semiconductor layer 2 by the light incident on the light-receiving operation part 51. With the generated electron-hole pairs, a current amplification occurs with a low voltage since the voltage near the avalanche breakdown is relatively low in the P⁻-type semiconductor layer 2 interposed between the P⁺-type semiconductor region 5 and the N⁺-type semiconductor region 8, i.e., the P⁻-type semiconductor layer 2 having a large electrical potential gradient, as shown in the energy band profile (potential distribution) between points a and b in FIG. 2B. In a portion of the P⁻-type semiconductor layer 2 that is interposed between the strip-shaped portions of the P⁺-type semiconductor region 5, there is a sufficient distance from the N⁺-type semiconductor region 8 and therefore the electrical potential gradient is relatively small, with a depletion layer expanding therein, as shown in the energy band profile (potential distribution) between points c and d in FIG. 2C. Therefore, a current amplification does not occur with the avalanche breakdown voltage of the P⁻-type semiconductor layer 2 interposed between the P⁺-type semiconductor region 5 and the N⁺-type semiconductor region 8. Conversely, in the portion of the P⁻-type semiconductor layer 2 that is interposed between the strip-shaped portions of the P⁺-type semiconductor region 5, a depletion layer expands sufficiently, thereby realizing a reduction in the capacitance. This is important in determining the response speed of the light-receiving operation part 51. Specifically, since the response speed can be represented by the frequency characteristics fc as follows: fc=1/2πCR (C: capacitance, R: resistance), it is possible to reduce the capacitance C and to thereby improve the frequency characteristics fc by forming the P⁺-type semiconductor region 5 with a plurality of strip-shaped portions as described in the present embodiment. In the light-receiving operation part 51 of the present embodiment, a large electrical potential gradient is realized near the surface of the light-receiving operation part 51, whereby it is possible to perform a sufficient current amplification even for light of a short wavelength for which the light absorption near the surface is dominant.

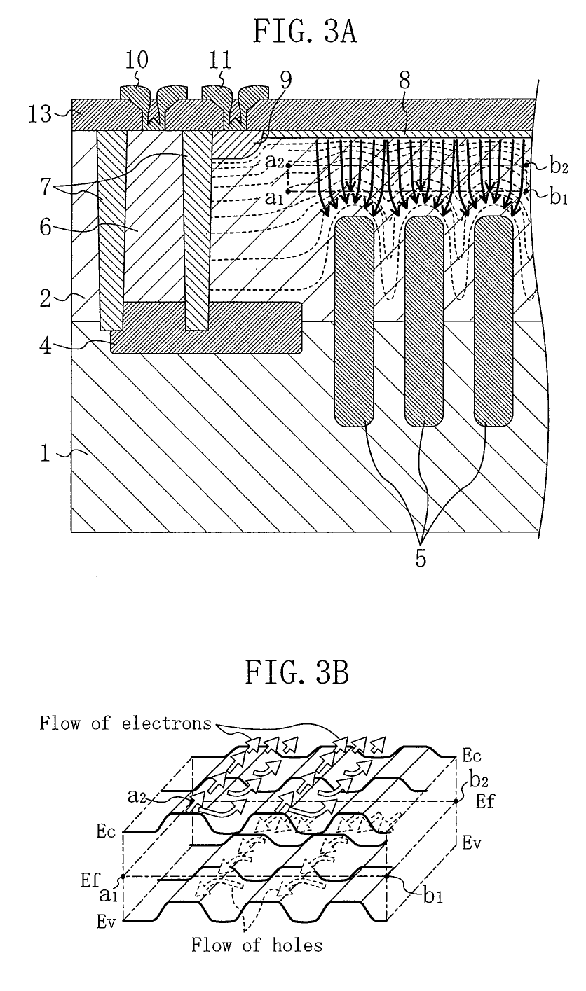

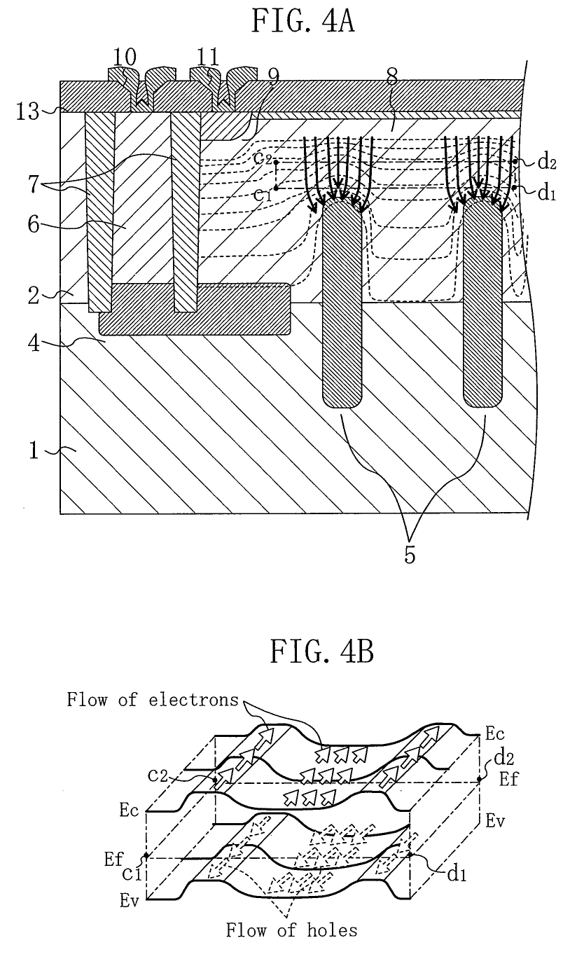

Next, the influence of the width of the portion of the P⁻-type semiconductor layer 2 that is interposed between the strip-shaped portions of the P⁺-type semiconductor region 5 in the light-receiving operation part 51 of the present embodiment will be described. FIG. 3A is similar to the cross-sectional view of FIG. 1 with the addition of equipotential lines (broken lines in the figure) and lines of electric force (arrows in the figure) for illustrating the light-receiving operation and the current amplification operation in a case where the width of the P⁻-type semiconductor layer 2 is relatively small in the light-receiving operation part 51 of the present embodiment, and FIG. 3B shows the potential distribution across the region a₁-a₂-b₂-b₁ in FIG. 3A. FIG. 4A is similar to the cross-sectional view of FIG. 1 with the addition of equipotential lines (broken lines in the figure) and lines of electric force (arrows in the figure) for illustrating the light-receiving operation and the current amplification operation in a case where the width of the P⁻-type semiconductor layer 2 is relatively large in the light-receiving operation part 51 of the present embodiment, and FIG. 4B shows the potential distribution across the region c₁-c₂-d₂-d₁ in FIG. 4A.

As shown in FIGS. 3A and 3B, in a case where the width of the portion of the P⁻-type semiconductor layer 2 that is interposed between the strip-shaped portions of the P⁺-type semiconductor region 5 in the light-receiving operation part 51 of the present embodiment is small, the avalanche amplification occurring in an upper portion of the P⁻-type semiconductor layer 2 spreads into the portion of the P⁻-type semiconductor layer 2 interposed between the portions of the P⁺-type semiconductor region 5, whereby it is possible to cause the avalanche amplification entirely across the vicinity of the surface of the light-receiving operation part 51 while maintaining the low capacitance state. On the other hand, as shown in FIGS. 4A and 4B, in a case where the width of the portion of the P⁻-type semiconductor layer 2 interposed between the strip-shaped portions of the P⁺-type semiconductor region 5 in the light-receiving operation part 51 of the present embodiment is large, the area over which the avalanche amplification occurs is reduced, thus resulting in a structure disadvantageous for the realization of a high light-receiving sensitivity. Therefore, in the light-receiving operation part 51 of the present embodiment, it is preferred that to reduce the width of the portion of the P⁻-type semiconductor layer 2 interposed between the strip-shaped portions of the P⁺-type semiconductor region 5. Specifically, it is preferred that the interval between the portions of the P⁺-type semiconductor region 5 is substantially equal to or less than the interval between the P⁺-type semiconductor region 5 and the N⁺-type semiconductor region 8.

As described above, with the optical semiconductor device of the present embodiment, the light-receiving element portion 50 including the light-receiving operation part 51 for generating a photoelectric current and performing the current amplification is provided on the P⁻-type semiconductor substrate 1. Therefore, it is possible to convert the optical signal received as incident light to a photoelectric current and to amplify the photoelectric current, whereby it is possible to detect an optical signal even if the power of the incident light is small.

Particularly, in the optical semiconductor device of the present embodiment, the avalanche amplification can be performed with the application of a low voltage in the P⁻-type semiconductor layer 2 interposed between the N⁺-type semiconductor region 8 having a high impurity concentration and the P⁺-type semiconductor region 5 having a high impurity concentration, whereby it is possible to amplify a photoelectric current carrying optical signal information. Therefore, it is possible to improve the light-receiving sensitivity without increasing the thickness of the N⁺-type semiconductor region 8, and it is thus possible to also improve the high-speed response property. Moreover, since it is not necessary to increase the thickness of the N⁺-type semiconductor region 8, it is possible to improve the light-receiving sensitivity not only for infrared light and red light, but also for blue light. Moreover, since the P⁺-type semiconductor region 5 is selectively formed between the P⁻-type semiconductor substrate 1 and the P⁻-type semiconductor layer 2, the P⁻-type semiconductor layer 2 is present even at a position sufficiently distant from the N⁺-type semiconductor region 8 in a region where the P⁺-type semiconductor region 5 is absent, whereby the electrical potential gradient will be relatively small and the depletion layer will be sufficiently expanded. Therefore, it is possible to realize a reduction in the capacitance, and it is thus possible to also improve the frequency characteristics.

As described above, with the optical semiconductor device of the present embodiment, the current formed by the carriers generated in the N⁺-type semiconductor region 8 or the P⁻-type semiconductor layer 2 can be amplified by the light-receiving operation part 51, whereby it is possible to obtain a sufficient light-receiving sensitivity and a sufficient high-speed response property even for light of a short wavelength such as blue light. With the P⁺-type semiconductor region 5, the avalanche voltage for causing the current amplification can be set to a low voltage, whereby it is possible to reduce the power consumption of the optical semiconductor device, allowing for its use in a wide range of applications.

In the present embodiment, the concentration of the impurity contained in a semiconductor layer or a semiconductor region of the light-receiving element portion 50 is not limited to the values shown above. Nevertheless, for the formation of a depletion layer during operation, it is preferred that the concentration of the impurity contained in the P⁻-type semiconductor layer 2 is substantially equal to or less than the concentration of the impurity contained in the P⁻-type semiconductor substrate 1 and is lower than the concentration of the impurity contained in the N⁺-type semiconductor region 8. The P⁻-type semiconductor layer 2 may be replaced by an intrinsic semiconductor layer or an N-type semiconductor layer having a concentration lower than that of the P⁻-type semiconductor substrate 1 and that of the N⁺-type semiconductor region 8. In view of the contact characteristics, the concentration of the impurity contained in the cathode contact layer 9 is preferably higher than the concentration of the impurity contained in the N⁺-type semiconductor region 8. Moreover, in order to reduce the contact resistance with the anode electrode 10, it is preferred that the concentration of the impurity contained in the P⁺-type semiconductor region 6 and the P⁺-type semiconductor region 4 is higher than the concentration of the impurity contained in the P⁻-type semiconductor substrate 1. Moreover, the P⁺-type semiconductor region 4 may be omitted.

In the present embodiment, the device can be operated even if the conductivity type of the impurity contained in the semiconductor layer or the semiconductor region of the light-receiving element portion 50 is reversed.

In the present embodiment, the material of the P⁻-type semiconductor substrate 1 is most preferably silicon, but another semiconductor such as SiGe, a compound semiconductor, etc., may be used instead of silicon.

A method for manufacturing the light-receiving element portion 50 of the present embodiment will now be described briefly. The light-receiving element portion 50 of the present embodiment can be produced by production techniques known in the art. Specifically, first, the P⁻-type semiconductor substrate 1 is implanted with ions of a P-type impurity to form the P⁺-type semiconductor regions 4 and 5. Then, the P⁻-type semiconductor layer 2 having a thickness of about 2 μm is epitaxially grown on the P⁻-type semiconductor substrate 1 by, for example, a CVD (chemical vapor deposition) method, or the like. Then, the P⁺-type semiconductor region 6, the N⁺-type semiconductor region 8 and the cathode contact layer 9 are successively formed in the P⁻-type semiconductor layer 2. Then, the device isolation layer 7 is formed by an STI (shallow trench isolation) formation technique known in the art. Then, after the protection insulative film 13 is formed on the P⁻-type semiconductor layer 2, the protection insulative film 13 is etched to form openings on contact layers, and the anode electrode 10 and the cathode electrode 11 are formed.

### Second Example Embodiment

An optical semiconductor device (OEIC device) according to a second example embodiment will now be described with reference to the drawings. The optical semiconductor device of the second example embodiment is obtained by integrating the light-receiving element portion 50 of the first example embodiment shown in FIG. 1 with a bipolar transistor, a MOS (metal oxide semiconductor) transistor, etc., on the same substrate. The process of forming each semiconductor region of the light-receiving element portion 50 and the process of forming each semiconductor region of the above transistor may share a common process, and therefore the light-receiving element portion 50 and the various transistors can easily be integrated together on the same substrate.

FIG. 5 is a cross-sectional view showing an example of the optical semiconductor device according to the second example embodiment. In FIG. 5, like elements to those of the first example embodiment shown in FIG. 1 are denoted by like reference numerals and will not be further described below.

As shown in FIG. 5, the first transistor portion 60 where an NPN bipolar transistor and a VPNP transistor are provided and the second transistor portion 70 where a CMOS (complementary metal oxide semiconductor) transistor is provided are formed on the P⁻-type semiconductor substrate 1, in addition to the light-receiving element portion 50. The light-receiving element portion 50, the first transistor portion 60 and the second transistor portion 70 are separated from one another by the device isolation layer 7, which extends to reach the P⁻-type semiconductor substrate 1 or a P⁺-type semiconductor region 21 to be described later.

The configuration of each of the first transistor portion 60 and the second transistor portion 70 will now be described in detail.

The first transistor portion 60 includes a bipolar transistor (NPN-Tr), including an N-type collector portion, a P-type base portion and an N-type emitter portion, and a bipolar transistor (VPNP-Tr), including a P-type collector portion, an N-type base portion and a P-type emitter portion.

The N-type collector portion of the NPN-Tr includes an N-type collector region 14 formed by diffusing an N-type impurity into the P⁻-type semiconductor layer 2, an N⁺-type semiconductor region 40 and an N-type semiconductor region 41 to be the collector contact, and a collector electrode 18 formed on the N-type semiconductor region 41. The P-type base portion includes an active base layer 15 of a P-type semiconductor, a base contact region 16 of a P⁺-type semiconductor, and a base electrode 19 formed on the base contact region 16. The N-type emitter portion includes an emitter region 17 formed on the active base layer 15 and containing an N-type impurity, a polycrystalline semiconductor layer 12a formed on the emitter region 17 and doped with a high concentration of an N-type impurity, and an N-type emitter electrode 20 formed on the polycrystalline semiconductor layer 12a.

The P-type collector portion of the PNP-Tr includes the P⁺-type semiconductor region 21 to be the collector contact, a P-type semiconductor region 22 formed on the P⁺-type semiconductor region 21 and surrounded by the device isolation layer 7, and a P-type collector region 26 formed on the P-type semiconductor region 22. An N-type semiconductor region 43 is formed under the P⁺-type semiconductor region 21 in order to electrically separate the P⁻-type semiconductor substrate 1 and the PNP-Tr from each other. The N-type base portion includes an N-type active base region 23 formed on a P-type semiconductor region 42, an N-type contact base region 24 formed on the P-type semiconductor region 42 so as to be in contact with the N-type active base region 23, and a base electrode 28 formed on the N-type contact base region 24. The P-type emitter portion includes a P-type emitter region 25 formed on the N-type active base region 23, a polycrystalline semiconductor layer 12b formed on the P-type emitter region 25, and an emitter electrode 27 formed on the polycrystalline semiconductor layer 12b.

As described above in the first example embodiment, with the light-receiving element portion 50, it is possible to improve the light-receiving characteristic by the avalanche amplification, whereby it is possible to form the NPN-Tr and the VPNP-Tr of the first transistor portion 60 without being restricted by the light-receiving element characteristics.

Next, the second transistor portion 70 includes an N channel-type MOS transistor (NMOS) and a P channel-type MOS transistor (PMOS). The MOS transistors are separated from each other by the device isolation layer 7. The diffusion layer of each MOS transistor is formed on the P⁻-type semiconductor layer 2. Specifically, the PMOS includes an N-type well region 44, a P-type source region 30, a P-type drain region 29, a P-type polycrystalline semiconductor layer 33 to be the gate electrode, a source electrode 36, and a drain electrode 35, whereas the NMOS includes a P-type well region 45, an N-type source region 32, an N-type drain region 31, an N-type polycrystalline semiconductor layer 34 to be the gate electrode, a source electrode 38, and a drain electrode 37.

By using the light-receiving element portion 50, each MOS transistor of the second transistor portion 70 can also be designed without being restricted by the light-receiving sensitivity of the light-receiving element portion 50.

As described above, the optical semiconductor device of the present embodiment provides, in addition to advantages similar to those described above in the first example embodiment, an advantage that a light-receiving element having a high-speed response property and a high light-receiving sensitivity for three types of light source wavelengths can be mounted together with an NPN-Tr, a VPNP-Tr, an NMOS and a PMOS on the same chip. Moreover, the light-receiving sensitivity of the light-receiving element portion 50 can be made sufficiently high without employing a special configuration, e.g., increasing the thickness of the N⁺-type semiconductor region 8 of the light-receiving element portion 50. Therefore, when various transistors are provided on the same substrate, it is possible to reduce the restrictions to be imposed on the structure of each transistor in order to ensure the characteristics of the light-receiving element portion 50.

With the optical semiconductor device of the present embodiment, there is no limitations on the types and the total number of transistors to be mounted together with the light-receiving element portion 50.

What is claimed is:

1. An optical semiconductor device comprising:
a light-receiving element on a semiconductor substrate of a first conductivity type, the light-receiving element including a light-receiving portion for converting incident light to an electrical current signal and performing a current amplification,
wherein the light-receiving portion includes
a semiconductor layer formed on the semiconductor substrate and having an impurity concentration substantially equal to or less than that of the semiconductor substrate;
a first semiconductor region of a second conductivity type formed on the semiconductor layer and having an impurity concentration higher than that of the semiconductor layer; and
a second semiconductor region of the first conductivity type selectively formed between the semiconductor substrate and the semiconductor layer and having an impurity concentration higher than those of the semiconductor substrate and the semiconductor layer.

2. The optical semiconductor device of claim 1, wherein a conductivity type of the semiconductor layer is the first conductivity type.

3. The optical semiconductor device of claim 1, further comprising:
a device isolation layer delimiting the light-receiving portion; and
a third semiconductor region of the first conductivity type formed on an outer side of the light-receiving portion with the device isolation layer being interposed between the third semiconductor region and the light-receiving portion.

4. The optical semiconductor device of claim 3, wherein the third semiconductor region has an impurity concentration higher than that of the semiconductor substrate.

5. The optical semiconductor device of claim 3, wherein the second semiconductor region is placed in a region surrounded by the device isolation layer.

6. The optical semiconductor device of claim 3, further comprising a fourth semiconductor region of the first conductivity type formed between the semiconductor substrate and the third semiconductor region.

7. The optical semiconductor device of claim 6, wherein the fourth semiconductor region has an impurity concentration higher than that of the semiconductor substrate.

8. The optical semiconductor device of claim 6, wherein a bottom of the device isolation layer is located above a bottom of the fourth semiconductor region.

9. The optical semiconductor device of claim 6, wherein the second semiconductor region has an impurity concentration substantially equal to or greater than that of the fourth semiconductor region.

10. The optical semiconductor device of claim 1, wherein a portion of the semiconductor layer is present between the second semiconductor region and the first semiconductor region.

11. The optical semiconductor device of claim 10, wherein the current amplification is performed in the portion of the semiconductor layer which is present between the second semiconductor region and the first semiconductor region.

12. The optical semiconductor device of claim 11, wherein a voltage is applied to the portion of the semiconductor layer which is present between the second semiconductor region and the first semiconductor region to thereby amplify the electrical current signal in avalanche amplification, thus performing the current amplification.

13. The optical semiconductor device of claim 1, wherein the second semiconductor region is formed by a plurality of portions separate from one another, with a portion of the semiconductor layer being present between the plurality of portions.

14. The optical semiconductor device of claim 1, further comprising a first transistor portion including a bipolar transistor on the semiconductor substrate.

15. The optical semiconductor device of claim 1, further comprising a second transistor portion including a MOS transistor on the semiconductor substrate.
